(19) United States
(12) Patent Application Publication
(10) Pub. No.: US 2025/0336729 A1
(43) Pub. Date: Oct. 30, 2025

(54) SECTION YIELDING IN STACKED MEMORY ARCHITECTURES

(71) Applicant: Micron Technology, Inc., Boise, ID (US)

(72) Inventors: Sai Krishna Mylavarapu, Folsom, CA (US); Todd A. Marquart, Boise, ID (US)

(21) Appl. No.: 19/170,615

(22) Filed: Apr. 4, 2025

Related U.S. Application Data
(60) Provisional application No. 63/640,652, filed on Apr. 30, 2024.

(51) Int. Cl. H01L 21/66; H01L 25/16; H10B 80/00

(52) U.S. Cl. CPC H01L 22/12; H01L 25/16; H10B 80/00

(57) ABSTRACT

Methods, systems, and devices for section yielding in stacked memory architectures are described. A system that implements a stacked semiconductor architecture may include wafers that are divided into die units having multiple sections, and the sections may be coupled as die unit section stacks through a stack of wafers. After stacking the semiconductor wafers (e.g., before or after singulation of die stacks from the stacked wafers), functionality of the die unit section stacks may be evaluated. If a die unit section stack is found to include an error or relatively low performance, the die unit section stack may be disabled, such that other die unit section stacks of a stacked die assembly may be operated (e.g., operated in accordance with a capacity or throughput associated with the remaining memory die unit section stacks).

### CROSS REFERENCE

The present Application for Patent claims priority to U.S. Patent Application No. 63/640,652 by Mylavarapu et al., entitled “SECTION YIELDING IN STACKED MEMORY ARCHITECTURES,” filed Apr. 30, 2024, which is assigned to the assignee hereof, and which is expressly incorporated by reference in its entirety herein.

### TECHNICAL FIELD

The following relates to one or more systems for memory, including section yielding in stacked memory architectures.

### BACKGROUND

Memory devices are used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored by the memory cell. To store information, a memory device may write (e.g., program, set, assign) states to the memory cells. To access stored information, a memory device may read (e.g., sense, detect, retrieve, determine) states from the memory cells.

### BRIEF DESCRIPTION OF THE DRAWINGS

FIG. 1 shows an example of a system that supports section yielding in stacked memory architectures in accordance with examples as disclosed herein.

FIG. 2 shows an example of a system that supports section yielding in stacked memory architectures in accordance with examples as disclosed herein.

FIG. 3 shows an example of a wafer that supports section yielding in stacked memory architectures in accordance with examples as disclosed herein.

FIG. 4 shows an example of a wafer assembly that supports section yielding in stacked memory architectures in accordance with examples as disclosed herein.

FIG. 5 shows an example of a die assembly that supports section yielding in stacked memory architectures in accordance with examples as disclosed herein.

FIG. 6 shows a flowchart illustrating a method or methods that support section yielding in stacked memory architectures in accordance with examples as disclosed herein.

### DETAILED DESCRIPTION

Some semiconductor systems (e.g., memory systems, processor systems) may include a stack of semiconductor components (e.g., semiconductor dies), which may include one or more memory dies (e.g., array dies) or one or more stacks of memory dies that are stacked with a logic die that is operable to access a set of memory arrays distributed across the one or more memory dies. Such a stacked architecture may be implemented as part of a high bandwidth memory (HBM) system or a coupled dynamic random access memory (DRAM) system, among other examples, and may support solutions for memory-centric logic, such as graphics processing units (GPUs), among other implementations. In some examples, an HBM system may include one or more memory dies coupled (e.g., bonded, stacked) with a logic die. In some examples, a 3D stacked memory system may be closely coupled (e.g., physically coupled, electrically coupled, directly coupled) with a processor, such as a GPU or other host device, as part of a physical memory map accessible to the processor. A logic die may include various components such as interface blocks (e.g., memory interface blocks, interface circuitry), logic blocks, controllers, processors, and other components. A semiconductor component (e.g., a semiconductor unit, a semiconductor subsystem), such as a logic die, may be formed as a single die with relevant circuitry, or may be formed with multiple die portions (e.g., relatively smaller dies, dies each including a respective subset of components of a logic unit) that may be referred to as “chiplets” (e.g., logic chiplets), among other examples.

To manufacture systems that implement a stacked semiconductor architecture (e.g., an HBM system, a 3D stacked memory system), semiconductor wafers that include multiple die units may be stacked and coupled (e.g., bonded) together, and respective stacks of coupled die units may be separated (e.g., cut, divided, singulated) from the stack of semiconductor wafers (e.g., rather than selecting individual semiconductor dies for stacking and coupling). Wafers with a relatively high yield of die units, such as wafers that include relatively fewer die units with defects (e.g., failures), may be selected for inclusion in a wafer stack. However, a non-perfect yield of the wafers may be compounded in the stack of wafers, such that a yield of a resulting stack of die units separated from the wafer stack may be reduced. For example, an eight-high array die stack that is separated from a stack of wafers that each have approximately 90% yield may have a yield of approximately 40%. As such, performance (e.g., latency, bandwidth, storage capacity) or yield of semiconductor systems may be adversely affected by such stacking.

In accordance with techniques described herein, a system that implements a stacked semiconductor architecture may include wafers that are divided into die units having multiple sections, and the sections may be coupled as die unit section stacks through a stack of wafers. After stacking the semiconductor wafers (e.g., before or after singulation of die stacks from the stacked wafers), functionality of the die unit section stacks may be evaluated. If a die unit section stack is found to include an error or relatively low performance, the die unit section stack may be disabled, such that other die unit section stacks of a stacked die assembly may be operated (e.g., operated in accordance with a capacity or throughput associated with the remaining memory die unit section stacks).

Supporting section yielding in accordance with the described techniques may increase the yield of a semiconductor system that implements a stacked architecture, such as an HBM system or 3D stacked memory system, for example, by supporting partial implementation of stacked die assemblies without discarding the associated wafers in the case of faulty die unit sections. As such, manufacturing performance of such systems may be improved, and a time-to-market may be reduced. For example, products released to the market may be associated with yield constraints, and improving yield via section yielding techniques described herein may enable such constraints to be satisfied without improving manufacturing techniques to increase the yield of individual semiconductor wafers, which may involve a delay before such improvements are realized. Additionally, or alternatively. section yielding techniques described herein may reduce costs as a final yield of an array die stack may be unknown until after it is coupled with a logic system or host system. Accordingly, if the yield does not meet yield constraints, the entire system, including the array dies and logic system or host system, may be discarded. Thus, improving array die stack yield using section yielding techniques described herein may increase the likelihood that yield constraints are met, thereby reducing costs of manufacturing HBM systems or 3D stacked memory systems, among other systems.

In addition to applicability in memory systems as described herein, techniques for section yielding in stacked memory architectures may be generally implemented to improve the sustainability of various electronic devices and systems. As the use of electronic devices has become even more widespread, the amount of energy used and harmful emissions associated with production of electronic devices and device operation has increased. Further, the amount of waste (e.g., electronic waste) associated with disposal of electronic devices may also pose environmental concerns. Implementing the techniques described herein may improve the impact related to electronic devices by supporting partial implementation of stacked die assemblies without discarding entire components for point failures, which may reduce electronic waste, among other benefits.

Features of the disclosure are illustrated and described in the context of systems and architectures. Features of the disclosure are further illustrated and described in the context of a semiconductor architecture, a semiconductor architecture cross-section, a die unit stack cross-section, and flowcharts.

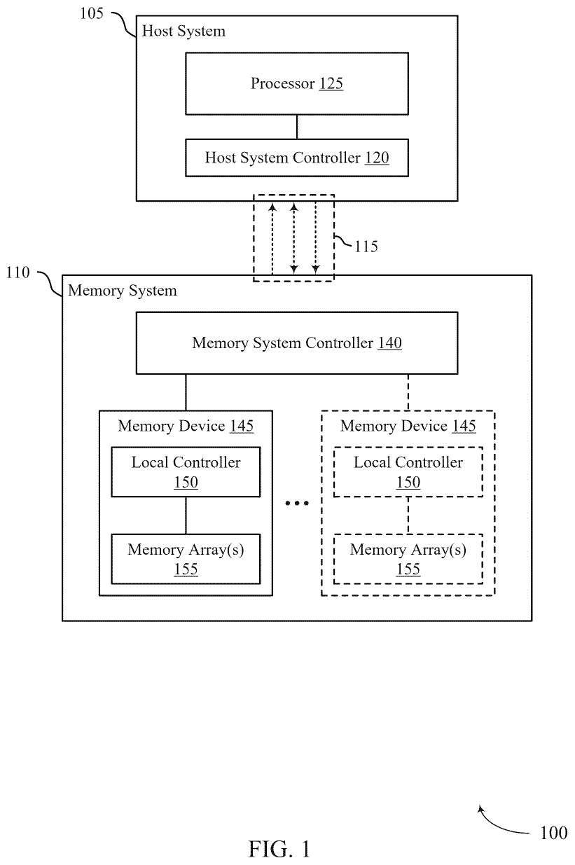

FIG. 1 shows an example of a system 100 that supports section yielding in stacked memory architectures in accordance with examples as disclosed herein. The system 100 may include portions of an electronic device, such as a computing device, a mobile computing device, a wireless communications device, a graphics processing device, a vehicle, a smartphone, a wearable device, an internet-connected device, a vehicle controller, a system on a chip (SoC), or other stationary or portable electronic system, among other examples. The system 100 includes a host system 105, a memory system 110, and one or more channels 115 coupling the host system 105 with the memory system 110 (e.g., to support a communicative coupling). The system 100 may include any quantity of one or more memory systems 110 coupled with the host system 105.

The host system 105 may include one or more components (e.g., circuitry, processing circuitry, application processing circuitry, one or more processing components) that use memory to execute processes (e.g., applications, functions, computations), any one or more of which may be referred to as or be included in a processor 125. The processor 125 may include at least one of one or more processing elements that may be co-located or distributed, including a general-purpose processor, a digital signal processor (DSP), an application-specific integrated circuit (ASIC), a field-programmable gate array (FPGA) or other programmable logic device, a controller, discrete gate or transistor logic, one or more discrete hardware components, or a combination thereof. The processor 125 may be an example of a central processing unit (CPU), a graphics processing unit (GPU), a general-purpose GPU (GPGPU), or an SoC or a component thereof, among other examples.

In some examples, the system 100 or the host system 105 may include an input component, an output component, or a combination thereof. Input components may include a sensor, a microphone, a keyboard, another processor (e.g., on a printed circuit board), an interface (e.g., a user interface, an interface between other devices), or a peripheral that interfaces with system 100 via one or more peripheral components, among other examples. Output components may include a display, audio speakers, a printing device, another processor on a printed circuit board, or a peripheral that interfaces with the system 100 via one or more peripheral components, among other examples.

The host system 105 may also include at least one of one or more components (e.g., circuitry, logic, instructions) that implement the functions of an external memory controller (e.g., a host system memory controller), which may be referred to as or be included in a host system controller 120. For example, a host system controller 120 may issue commands or other signaling for operating the memory system 110, such as write commands, read commands, configuration signaling or other operational signaling. In some examples, the host system controller 120, or associated functions described herein, may be implemented by or be part of the processor 125. For example, a host system controller 120 may be hardware, instructions (e.g., software, firmware), or a combination thereof implemented by the processor 125 or other component of the host system 105. In various examples, a host system 105 or a host system controller 120 may be referred to as a host.

The memory system 110 provides physical memory locations (e.g., addresses) that may be used or referenced by the system 100. The memory system 110 may include a memory system controller 140 and one or more memory devices 145 (e.g., memory packages, memory dies, portions of a memory die) operable to store data. The memory system 110 may be configurable for operations with different types of host systems 105, and may respond to commands from the host system 105 (e.g., from a host system controller 120). For example, the memory system 110 (e.g., a memory system controller 140) may receive a write command indicating that the memory system 110 is to store data received from the host system 105, or receive a read command indicating that the memory system 110 is to provide data stored in a memory device 145 to the host system 105, or receive a refresh command indicating that the memory system 110 is to refresh data stored in a memory device 145, among other types of commands and operations.

A memory system controller 140 may include at least one of one or more components (e.g., circuitry, logic, instructions) operable to control operations of the memory system 110. A memory system controller 140 may include hardware or instructions that support the memory system 110 performing various operations, and may be operable to receive, transmit, or respond to commands, data, or control information related to operations of the memory system 110. A memory system controller 140 may be operable to communicate with one or more of a host system controller 120, one or more memory devices 145, or a processor 125. In some examples, a memory system controller 140 may control operations of the memory system 110 in cooperation with the host system controller 120, a local controller 150 of a memory device 145, or any combination thereof. Although the example of memory system controller 140 is illustrated as a separate component of the memory system 110, in some examples, aspects of the functionality of the memory system 110 may be implemented by a processor 125, a host system controller 120, at least one of one or more local controllers 150, or any combination thereof.

Each memory device 145 may include a local controller 150 (e.g., a logic controller, an interface controller, one or more processors) and one or more memory arrays 155. A memory array 155 may be a collection of memory cells (e.g., a two-dimensional array, a three-dimensional array, an array of one or more semiconductor components), with each memory cell being operable to store data (e.g., as one or more stored bits). Each memory array 155 may include memory cells of various architectures, such as random access memory (RAM) cells, dynamic RAM (DRAM) cells, synchronous dynamic RAM (SDRAM) cells, static RAM (SRAM) cells, ferroelectric RAM (FeRAM) cells, magnetic RAM (MRAM) cells, resistive RAM (RRAM) cells, phase change memory (PCM) cells, chalcogenide memory cells, not-or (NOR) memory cells, and not-and (NAND) memory cells, or any combination thereof.

A local controller 150 may include at least one of one or more components (e.g., circuitry, logic, instructions) operable to control operations of a memory device 145. In some examples, a local controller 150 may be operable to communicate (e.g., receive or transmit data or commands or both) with a memory system controller 140. In some examples, a memory system 110 may not include a memory system controller 140, and a local controller 150 or a host system controller 120 may perform functions of a memory system controller 140 described herein. In some examples, a local controller 150, or a memory system controller 140, or both may include decoding components operable for accessing addresses of a memory array 155, sense components for sensing states of memory cells of a memory array 155, write components for writing states to memory cells of a memory array 155, or various other components operable for supporting described operations of a memory system 110.

A host system 105 (e.g., a host system controller 120) and a memory system 110 (e.g., a memory system controller 140) may communicate information (e.g., data, commands, control information, configuration information, timing information) using one or more channels 115. Each channel 115 may be an example of a transmission medium that carries information, and each channel 115 may include one or more signal paths (e.g., a transmission medium, an electrical conductor, a conductive path) between terminals (e.g., nodes, pins, contacts) associated with the components of the system 100. A terminal may be an example of a conductive input or output point of a device of the system 100, and a terminal may be operable as part of a channel 115. In some implementations, at least the channels 115 between a host system 105 and a memory system 110 may include or be referred to as a host interface (e.g., a physical host interface). To support communications over channels 115, a host system 105 (e.g., a host system controller 120) and a memory system 110 (e.g., a memory system controller 140) may include receivers (e.g., latches) for receiving signals, transmitters (e.g., drivers) for transmitting signals, decoders for decoding or demodulating received signals, or encoders for encoding or modulating signals to be transmitted, among other components that support signaling over channels 115, which may be included in a respective interface portion of the respective system.

A channel 115 may be dedicated to communicating one or more types of information, and channels 115 may include unidirectional channels, bidirectional channels, or both. For example, the channels 115 may include one or more command/address channels, one or more clock signal channels, one or more data channels, among other channels or combinations thereof. In some examples, a channel 115 may be configured to provide power from one system to another (e.g., from the host system 105 to the memory system 110, in accordance with a regulated voltage). In some examples, at least a subset of channels 115 may be configured in accordance with a protocol (e.g., a logical protocol, a communications protocol, an operational protocol, an industry standard), which may support configured operations of and interactions between a host system 105 and a memory system 110.

In some examples, at least a portion of the system 100 may implement a stacked semiconductor architecture in which multiple semiconductor dies are physically and communicatively coupled (e.g., directly coupled, bonded). For example, at least one of the memory arrays 155 of a memory device 145 may be formed using one or more semiconductor dies (e.g., a single memory die, a stack of multiple memory dies), which may be stacked over another semiconductor die (e.g., a logic die) that includes at least a portion of a local controller 150. In some examples, a semiconductor die or die assembly may include at least a portion of or all of a local controller 150 and at least a portion of or all of a memory system controller 140, and such a semiconductor die or die assembly may be coupled with one or more memory dies, or one or more stacks of memory dies. In accordance with these and other examples, circuitry for accessing one or more memory arrays 155 (e.g., circuitry of a memory system 110) may be distributed among multiple semiconductor dies of a stack (e.g., a stack of multiple directly-coupled semiconductor dies). For example, a first die may include a set of multiple first interface blocks (e.g., memory interface blocks, instances of first interface circuitry) and one or more second dies may include corresponding second interface blocks, each coupled with a first interface block of the first die, which are each configured to access one or more memory arrays 155 of the second dies. In some examples, the system may include a controller (e.g., a memory controller, an interface controller, a host interface controller, at least a portion of a memory system controller 140) for each set of one or more first interface blocks to support access operations (e.g., to access one or more memory arrays 155) via the set of first interface blocks. In some examples, such a controller may be located in the same first die as the first interface blocks. In some examples, multiple semiconductor dies of a memory system 110 or of a system 100 (e.g., an HBM system including aspects of a memory system 110, a stacked semiconductor system including aspects of a memory system 110 and a host system 105) may include one or more array dies stacked with a logic die (e.g., that includes aspects of the host system 105, that is coupled with another die that includes the host system 105) that includes interface blocks operable to access a set of memory arrays 155 distributed across the one or more second dies.

To manufacture a system 100, or portion thereof (e.g., a memory system 110, a host system 105), that implements a stacked semiconductor architecture (e.g., an HBM system, a 3D stacked memory system), semiconductor wafers that include multiple die units may be stacked and coupled (e.g., bonded) together, and respective stacks of coupled die units may be separated (e.g., cut, divided, singulated) from the stack of semiconductor wafers (e.g., rather than selecting individual semiconductor dies for stacking and coupling). Wafers with a relatively high yield of die units, such as wafers that include relatively fewer die units with defects (e.g., failures), may be selected for inclusion in a wafer stack. However, a non-perfect yield of the wafers may be compounded in the stack of wafers, such that a yield of a resulting stack of die units separated from the wafer stack may be reduced. For example, an eight-high array die stack that is separated from a stack of wafers that each have approximately 90% yield may have a yield of approximately 40%. As such, performance (e.g., latency, bandwidth, storage capacity) or yield of semiconductor systems may be adversely affected by such stacking.

In accordance with techniques described herein, the system 100, or a portion thereof (e.g., a memory system 110, a host system 105), that implements a stacked semiconductor architecture may include wafers that are divided into die units having multiple sections, and the sections may be coupled as die unit section stacks through a stack of wafers. After stacking the semiconductor wafers (e.g., before or after singulation of die stacks from the stacked wafers), functionality of the die unit section stacks may be evaluated. If a die unit section stack is found to include an error or relatively low performance, the die unit section stack may be disabled, such that other die unit section stacks of a stacked die assembly may be operated (e.g., operated in accordance with a capacity or throughput associated with the remaining memory die unit section stacks).

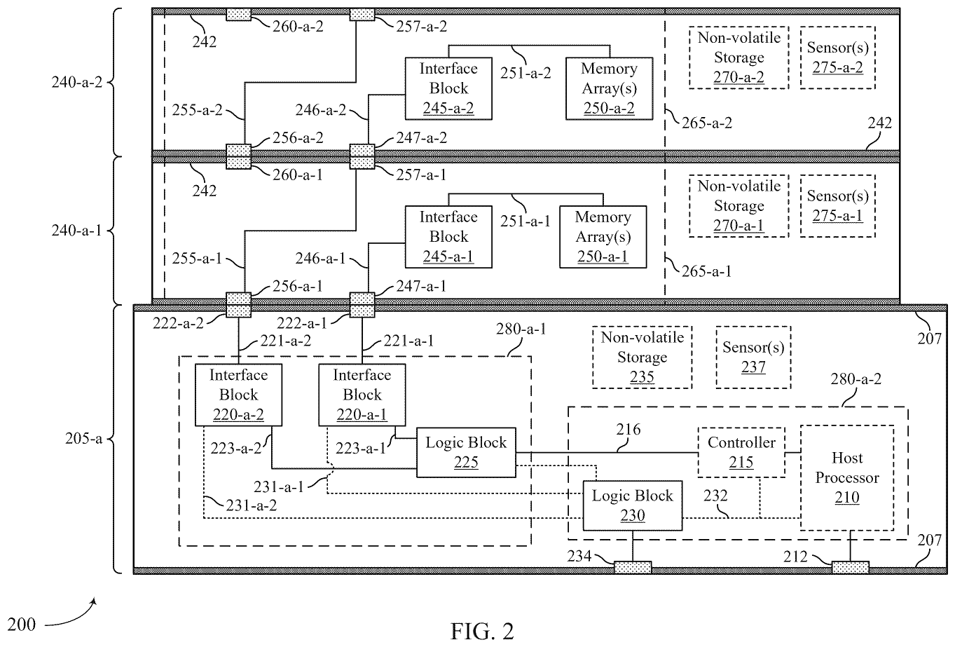

FIG. 2 shows an example of a system 200 (e.g., a semiconductor system, a system of coupled semiconductor dies, an HBM system, a 3D stacked memory system) that supports section yielding in stacked memory architectures in accordance with examples as disclosed herein. The system 200 illustrates an example of a die 205 (e.g., a die 205-a, a semiconductor die, a logic die, a processor die, a host die, a logic unit) that is coupled with one or more dies 240 (e.g., dies 240-a-1 and 240)-a-2, semiconductor dies, memory dies, array dies, memory units). A die 205 or a die 240 may be formed using a respective semiconductor substrate (e.g., a substrate of crystalline semiconductor material such as silicon, germanium, silicon-germanium, gallium arsenide, or gallium nitride), or a silicon-on-insulator (SOI) substrate (e.g., silicon-on-glass (SOG), silicon-on-sapphire (SOS)), or epitaxial semiconductor materials formed on another substrate, among other examples. Although the illustrated example of a system 200 includes two dies 240, a system 200 in accordance with the described techniques may include any quantity of one or more dies 240 (e.g., 8, 12, 16, or more dies 240) coupled with a die 205, among other dies of a stack or other coupled layout. Further, although non-limiting examples of the system 200 herein are generally described in terms of applicability to memory systems, memory sub-systems, memory devices, or a combination thereof, examples of the system 200 are not so limited. For example, aspects of the present disclosure may be applied as well to any computing system, computing sub-system, processing system, processing sub-system, component, device, structure, or other types of systems or sub-systems used for applications such as data collecting, data processing, data storage, networking, communication, power, artificial intelligence, system-on-a-chip, control, telemetry, sensing and monitoring, digital entertainment, or any combination thereof.

The system 200 illustrates an example of interface circuitry between a host and memory (e.g., via a host interface, via a physical host interface) that is implemented in (e.g., divided between) multiple semiconductor dies (e.g., a stack of directly-coupled dies). For example, the die 205-a may include a set of one or more interface blocks 220 (e.g., interface blocks 220-a-1 and 220-a-2, memory interface blocks), and each die 240 may include a set of one or more interface blocks 245 (e.g., access interface blocks) and one or more memory arrays 250 (e.g., die 240-a-1 including an interface block 245-a-1 coupled with a set of one or more memory arrays 250-a-1, die 240-a-2 including an interface block 245-a-2 coupled with a set of one or more memory arrays 250-a-2). The memory arrays 250 may be examples of memory arrays 155, and may include memory cells of various architectures, such as RAM, DRAM, SDRAM, SRAM, FeRAM, MRAM, RRAM, PCM, chalcogenide, NOR, or NAND memory cells, or any combination thereof.

Although the example of system 200 is illustrated with one interface block 245 included in each die 240, a die 240 in accordance with the described techniques may include any quantity of one or more interface blocks 245, each coupled with a respective set of one or more memory arrays 250, and each coupled with an interface block 220 of a die 205. Thus, the interface circuitry of a system 200 may include one or more interface blocks 220 of a die 205, with each interface block 220 being coupled with (e.g., in communication with) one or more interfaces block 245 of a die 240 (e.g., external to the die 205). In some examples, a coupled combination of an interface block 220 and an interface block 245 (e.g., coupled via a bus associated with one or more channels, such as one or more data channels, one or more control channels, one or more clock channels, one or more pseudo-channels, or a combination thereof) may include or be referred to as a data path associated with a respective set of one or more memory arrays 250.

In some implementations, a die 205 may include a host processor 210. A host processor 210 may be an example of a host system 105, or a portion thereof (e.g., a processor 125, aspects of a host system controller 120, or both). The host processor 210 may be configured to perform operations that implement storage of the memory arrays 250 (e.g., to support an application or other function of a host system 105, which may request access of the memory arrays 250). For example, the host processor 210 may receive data read from the memory arrays 250, or may transmit data to be written to the memory arrays 250, or both (e.g., in accordance with an application or other operations of the host processor 210). Additionally, or alternatively, a host processor 210 may be external to a die 205 (e.g., in HBM implementations), such as in another semiconductor die or other component that is coupled with (e.g., communicatively coupled with, directly coupled with, bonded with, coupled via another intervening component) the die 205 via one or more contacts 212 (e.g., externally-accessible terminals of the die 205).

A host processor 210 may be configured to communicate (e.g., transmit, receive) signaling with interface blocks 220 via a host interface 216 (e.g., a physical host interface), which may implement aspects of channels 115. For example, a host interface 216 may be configured in accordance with an industry standard, which may define channels, commands, clocking, and deterministic responses and timing, among other characteristics of the host interface 216. In some examples, a host interface 216 may provide a communicative coupling between physical or functional boundaries of a host system 105 and a memory system 110. For example, the host processor 210 may be configured to communicate access signaling (e.g., control signaling, access command signaling, data signaling, configuration signaling, clock signaling) via a host interface 216 to support access operations (e.g., read operations, write operations) on the memory arrays 250, among other operations. Although the example of system 200 includes a single host interface 216, a system in accordance with the described techniques may include any quantity of one or more host interfaces 216 for accessing memory arrays 250 of the system.

In some examples, a respective host interface 216 may be coupled between a set of one or more interface blocks 220 (e.g., interface blocks 220-a-1 and 220-a-2) and a respective controller 215. A controller 215 may be an example of control circuitry (e.g., memory controller circuitry, host interface control circuitry) associated with a host system 105, and may be associated with implementing respective instances of one or more aspects of a host system controller 120, or of a memory system controller 140, or a combination thereof. For example, a controller 215 may be operable to respond to indications (e.g., requests, commands) from the host processor 210 to access one or more memory arrays 250 in support of a function or application of the host processor 210, to transmit associated commands (e.g., for one or more interface blocks 220) to access the one or more memory arrays 250, and to communicate data (e.g., write data, read data) with the host processor 210, among other functions.

In some examples, one or more controllers 215 may be implemented in a die 205 (e.g., the same die that includes one or more interface blocks 220, in accordance with a command and address protocol) whether a host processor 210 is included in the die 205, or is external to the die 205. In some other examples, controllers 215 or associated circuitry or functionality may be implemented external to a die 205 (e.g., in another die, not shown, coupled with respective interface blocks 220 via respective terminals for each of the respective host interfaces 216, in an HBM implementation), which may be in the same die as or a different die from a die that includes a host processor 210. An interface block 220 may be operable via a single controller 215, or by one or more of a set of multiple controllers 215 (e.g., in accordance with a controller multiplexing scheme). In some other examples, aspects of one or more controllers 215 may be included in the host processor 210 (e.g., as a memory interface of the host processor 210, as a memory interface of a host system 105).

Although, in some examples, a controller 215 may be directly coupled with one or more interface blocks 220 (not shown), in some other examples, a controller 215 (e.g., a host interface 216) may be coupled with a set of multiple interface blocks 220 via a logic block 225 (e.g., logic circuitry for a channel set, logic circuitry for a host interface 216, multiplexing circuitry). For example, the logic block 225 may be coupled with the interface block 220-a-1 via a bus 223-a-1 and coupled with the interface block 220-a-2 via a bus 223-a-2. A controller 215 and one or more corresponding interface blocks 220 may communicate (e.g., collaborate) using the host interface 216 via a logic block 225 to perform one or more operations (e.g., scheduling operations, access operations, operations initiated by a host processor 210) associated with accessing a corresponding set of one or more memory arrays 250.

In some examples, a logic block 225, a controller 215, or a host interface 216, or a combination thereof may be associated with a “channel set” that corresponds to multiple memory array's 250 (e.g., for parallel or otherwise coordinated access of the multiple memory arrays 250). For example, such a channel set may be associated with multiple memory arrays 250 accessed via a single interface block 245, or multiple memory arrays 250 each accessed via a respective one of the interface blocks 245, or multiple memory arrays 250 each accessed via a respective one of the interface blocks 220, any of which may be associated with signaling via a single logic block 225, via a single host interface 216, or via a single controller 215. These and other configurations for implementing one or more channel sets in a system may support various techniques for parallelism and high bandwidth data transfer, memory management operations, repair and replacement techniques, or power and thermal distribution, among other techniques that leverage the described coupling of components and interfaces among multiple semiconductor dies (e.g., in accordance with a high bandwidth configuration of the system 200, in accordance with a closely-coupled configuration of the system 200). In some examples, such techniques may be implemented (e.g., at or using a logic block 225) in a manner that is transparent to the host interface 216 or other aspects of a host system 105.

In some examples, a host interface 216 may include a respective set of one or more signal paths for each logic block 225 or interface block 220, such that the host processor 210 may communicate with each logic block 225 or interface block 220 via its corresponding set of signal paths (e.g., in accordance with a selection of the corresponding set to perform access operations via a logic block 225 or interface block 220 that is selected by the host processor 210). Additionally, or alternatively, a host interface 216 may include one or more signal paths that are shared among multiple logic blocks 225 (not shown) or interface blocks 220, and a logic block 225, an interface block 220, or a host processor 210, or any of these may interpret, ignore, respond to, or inhibit response to signaling via shared signal paths of the host interface 216 based on a logical indication (e.g., an addressing indication associated with the logic block 225 or interface block 220, an interface enable signal, or an interface select signal, which may be provided by the host processor 210, the corresponding logic block 225, or the corresponding interface block 220 depending on signaling direction).

In some examples, a host processor 210 may determine to access an address (e.g., a logical address of a memory array 250, a physical address of a memory array 250, an address of a logic block 225, an address of an interface block 220, an address of a host interface 216, in response to an application of or supported by the host processor 210), and determine which controller 215 to transmit access signaling to for accessing the address (e.g., a controller 215, logic block 225, or interface block 220 corresponding to the address). In some examples, the address may be associated with a row of memory cells of the memory array 250, a column of memory cells of the memory array 250, or both. The host processor 210 may transmit access signaling (e.g., one or more access signals, one or more access commands) to the determined controller 215 and, in turn, the determined controller 215 may transmit access signaling to the corresponding logic block 225 or interface block 220 (e.g., in accordance with a command and address protocol). The corresponding interface block 220 may subsequently transmit access signaling to the coupled interface block 245 to access the determined address (e.g., of a corresponding memory array 250).

A die 205 may also include a logic block 230 (e.g., a shared logic block, a central logic block, common logic circuitry, evaluation circuitry, memory system configuration circuitry, memory system management circuitry), which may be configured to communicate (e.g., transmit, receive) signaling with the logic blocks 225, the interface blocks 220, or both of the die 205. In some cases, a logic block 230 may be configured to communicate information (e.g., commands, instructions, indications, data) with one or more logic blocks 225 or interface blocks 220 to facilitate operations of the system 200. For example, a logic block 230 may be configured to transmit configuration signaling (e.g., initialization signaling, evaluation signaling, mapping signaling), which may be received by logic blocks 225 or interface blocks 220 to support configuration of the logic blocks 225 or interface blocks 220, or other aspects of operating the dies 240 (e.g., via the respective interface blocks 245). A logic block 230 may be coupled with each logic block 225 and each interface block 220 via a respective bus 231. In some examples, such buses may each include a respective set of one or more signal paths, such that a logic block 230 may communicate with each logic block 225 or each interface block 220 via the respective set of signal paths. Additionally, or alternatively, such buses may include one or more signal paths that are shared among multiple logic blocks 225 or interface blocks 220 (not shown).

In some implementations, a logic block 230 may be configured to communicate (e.g., transmit, receive) signaling with a host processor 210 or one or more controllers 215 (e.g., via a bus 232, via a contact 212 for a host processor 210 or controller 215 external to a die 205), such that the logic block 230 may support an interface between the host processor 210 or one or more controllers 215 and the logic blocks 225 or interface blocks 220. For example, a host processor 210 or a controller 215 may be configured to transmit initialization signaling (e.g., boot commands), or other configuration or operational signaling, which may be received by a logic block 230 to support initialization, configuration, evaluation, or other operations of the logic blocks 225 or interface blocks 220. Additionally, or alternatively, in some implementations, a logic block 230 may be configured to communicate (e.g., transmit, receive) signaling with a component outside the system 200 (e.g., via a contact 234, which may be an externally-accessible terminal of the die 205), such that the logic block 230 may support an interface that bypasses a host processor 210 or controller 215. Additionally, or alternatively, a logic block 230 may communicate with a host processor 210 or a controller 215, and may communicate with one or more memory arrays 250 of one or more dies 240 (e.g., to perform self-test operations for access of memory arrays 250). In some examples, such implementations may support evaluations, configurations, or other operations of the system 200, via one or more contacts 234 that are accessible at a physical interface of the system, during manufacturing, assembly, validation, or other operation associated with the system 200 (e.g., before coupling with a host processor 210, without implementing a host processor 210, for operations independent of a host processor). Additionally, or alternatively, a logic block 230 may implement one or more aspects of a controller 215. For example, a logic block 230 may include or operate as one or more controllers 215 and may perform operations ascribed to a controller 215.

In some examples, respective signals may be routed between a die 205 and one or more dies 240. For example, each interface block 220 may be coupled with at least a respective bus 221 of the die 205, and a respective bus 246 of a die 240, that are configured to communicate signaling with a corresponding interface block 245 (e.g., via one or more associated signal paths). For example, the interface block 220-a-1 may be coupled with the interface block 245-a-1 via a bus 221-a-1 and a bus 246-a-1, and the interface block 220-a-2 may be coupled with the interface block 245-a-2 via a bus 221-a-2 and a bus 246-a-2. In some examples, a die 240 may include a bus that bypasses operational circuitry of the die 240 (e.g., that bypasses interface blocks 245 of a given die 240), such as a bus 255. For example, the interface block 220-a-2 may be coupled with the interface block 245-a-2 of the die 240-a-2 via a bus 255-a-1 of the die 240-a-1, which may bypass interface blocks 245 of the die 240-a-1. Such techniques may be extended for interconnection among more than two dies 240 (e.g., for interconnection via a respective bus 255 of multiple dies 240). In some implementations, at least a portion of a bus 221, a bus 246, or a bus 255, or any combination thereof may include one or more conductors in a redistribution layer (RDL) of a respective die (e.g., above or below a semiconductor substrate of the die). Additionally, or alternatively, in some implementations, at least a portion of a bus 221, a bus 246, or a bus 255, or any combination thereof may include one or more vias that are formed through a semiconductor substrate of a respective die (e.g., as one or more through-silicon vias (TSVs)).

The respective signal paths of buses 221, 246, and 255 may be coupled with one another, from one die to another, via various arrangements of contacts at the surfaces of interfacing dies (e.g., exposed contacts, metal surfaces of the respective dies). For example. the bus 221-a-1 may be coupled with the bus 246-a-1 via a contact 222-a-1 of (e.g., at a surface of) the die 205-a and a contact 247-a-1 of the die 240-a-1, the bus 221-a-2 may be coupled with the bus 255-a-1 via a contact 222-a-2 of the die 205 and a contact 256-a-1 of the die 240-a-1, the bus 255-a-1 may be coupled with the bus 246-a-2 via a contact 257-a-1 of the die 240-a-1 and a contact 247-a-2 of the die 240-a-2, and so on. Although each respective bus is illustrated with a single line, coupled via singular contacts, it is to be understood that each signal path of a given bus may be associated with respective contacts to support a separate communicative coupling via each signal path of the given bus. In some examples, a bus 255 may traverse a portion of a die 240 (e.g., in an in-plane direction, along a direction different from a thickness direction, in a waterfall arrangement, in a staircase arrangement), which may support an arrangement of contacts 222 along a surface of a die 205, among other contacts, being coupled with interface blocks 245 of different dies 240 along a stack direction (e.g., via respective contacts 256 and 257 that are non-overlapping when viewed along a thickness direction).

The interconnection of interfacing contacts may be supported by various techniques. For example, in a hybrid bonding implementation, interfacing contacts may be coupled by a fusion of conductive materials (e.g., electrically conductive materials) of the interfacing contacts (e.g., without solder or other intervening material between contacts). For example, in an assembled condition, the coupling of the die 205-a with the die 240-a-1 may include a conductive material of the contact 222-a-2 being fused with a conductive material of the contact 256-a-1, and the coupling of the die 240-a-1 with the die 240-a-2 may include a conductive material of the contact 257-a-1 being fused with a conductive material of the contact 247-a-2, and so on. In some examples, such coupling may include an inoperative fusion of contacts (e.g., a non-communicative coupling, a physical coupling), such as a fusion of the contact 260-a-1 with the contact 256-a-2, neither of which are coupled with operative circuitry of the dies 240-a-1 or 240-a-2. In some examples, such techniques may be implemented to improve coupling strength or uniformity (e.g., implementing contacts 260, which may not be operatively coupled with an interface block 245 or an interface block 220), or such a coupling may be a byproduct of a repetition of components that, in various configurations, may be operative or inoperative. (e.g., where, for dies 240 with a common arrangement of contacts 256 and 257, contacts 256-a-1 and 257-a-1 provide a communicative path between the interface block 245-a-2 and the interface block 220-a-2, but the contacts 256-a-2 and 257-a-2 do not provide a communicative path between an interface block 245 and an interface block 220).

In some examples, a fusion of conductive materials between dies (e.g., between contacts) may be accompanied by a fusion of other materials at one or more surfaces of the interfacing dies. For example, in an assembled condition, the coupling of the die 205 with the die 240-a-1 may include a dielectric material 207 (e.g., an electrically non-conductive material) of the die 205-a being fused with a dielectric material 242 of the die 240-a-1, and the coupling of the die 240-a-1 with the die 240-a-2 may include a dielectric material 242 of the die 240-a-1 being fused with a dielectric material 242 of the die 240-a-2. In some examples, such dielectric materials may include an oxide, a nitride, a carbide, an oxide-nitride, an oxide-carbide, or other conversion or doping of a substrate material (e.g., a semiconductor substrate material) or other material of the die 205 or dies 240, among other materials that may support such fusion. However, coupling among dies 205 and dies 240 may be implemented in accordance with other techniques, which may implement solder, adhesives, thermal interface materials, and other intervening materials or combinations of materials.

In some examples, dies 240 may be coupled in a stack (e.g., forming a “cube” or other arrangement of dies 240), and one or more of such stacks may subsequently be coupled with a die 205 (e.g., in a stack-to-chip bonding arrangement). In some examples, respective set(s) of one or more dies 240 may be coupled with each die 205 of multiple dies 205 as formed in a wafer (e.g., in a chip-to-wafer bonding arrangement, in a stack-to-wafer bonding arrangement, before cutting the wafer of dies 205), and the dies 205 of the wafer, each coupled with their respective set(s) of dies 240, may be separated from one another (e.g., by cutting at least the wafer of dies 205, by singulation). In some other examples, respective set(s) of one or more dies 240 may be coupled with a respective die 205 after the die 205 is separated from a wafer of dies 205 (e.g., in a chip-to-chip bonding arrangement). In some other examples, a respective set of one or more wafers, each including multiple dies 240, may be coupled in a stack (e.g., in a wafer-to-wafer bonding arrangement). In various examples, such techniques may be followed by separating stacks of dies 240 from the coupled wafers, or the stack of wafers having dies 240 may be coupled with another wafer including multiple dies 205 (e.g., in a second wafer-to-wafer bonding arrangement), which may be followed by separating systems 200 from the coupled wafers. In some other examples, wafer-to-wafer coupling techniques may be implemented by stacking one or more wafers of dies 240 (e.g., sequentially) over a wafer of dies 205 before separation into systems 200, among other examples for forming systems 200.

The buses 221, 246, and 255 may be implemented to provide a configured signaling (e.g., a coordinated signaling, a logical signaling, modulated signaling, digital signaling) between an interface block 220 and a corresponding interface block 245, which may involve various modulation or encoding techniques by a transmitting interface block (e.g., via a driver component of the transmitting interface block). In some examples, such signaling may be supported by (e.g., accompanied by) clock signaling communicated via the respective buses (e.g., in coordination with signal transmission). For example, the buses may be configured to convey one or more clock signals transmitted by the interface block 220 for reception by the interface block 245 (e.g., to trigger signal reception by a latch or other reception component of the interface block 245, to support clocked operations of the interface block 245). Additionally, or alternatively, the buses may be configured to convey one or more clock signals transmitted by the interface block 245 for reception by the interface block 220 (e.g., to trigger signal reception by a latch or other reception component of the interface block 220, to support clocked operations of the interface block 220). Such clock signals may be associated with the communication (e.g., unidirectional communication, bidirectional communication, deterministic communication) of various signaling, such as control signaling, command signaling, data signaling, or any combination thereof. For example, the buses may include one or more signal paths for communications of a data bus (e.g., one or more data channels, a DQ bus, via a data interface of the interface blocks) in accordance with one or more corresponding clock signals (e.g., data clock signals), or one or more signal paths for communications of a control bus (e.g., a command/address (C/A) bus, via a command interface of the interface blocks) in accordance with one or more clock signals (e.g., control clock signals), or any combination thereof.

Interface blocks 220, interface blocks 245, logic blocks 225, and a logic block 230 each may include circuitry (signaling circuitry, multiplexing circuitry, processing circuitry, controller circuitry, logic circuitry, physical components, hardware) in various configurations (e.g., hardware configurations, logic configurations, software or instruction configurations) that support the functionality allocated to the respective block for accessing or otherwise operating a corresponding set of memory arrays 250. For example, interface blocks 220 may include circuitry configured to perform a first subset of operations that support access of the memory arrays 250, and interface blocks 245 may include circuitry configured to perform a second subset of operations that support access of the memory arrays 250. In some examples. the interface blocks 220, the interface blocks 245, and logic blocks 225 may support a functional split or distribution of functionality associated with a memory system controller 140, a local controller 150, or both across multiple dies (e.g., a die 205 and at least one die 240). In some implementations, a logic block 230 may be configured to coordinate or configure aspects of the operations of the interface blocks 220, of the interface blocks 245, of the logic blocks 225, or a combination thereof, and may support implementing one or more aspects of a memory system controller 140. Such operations, or subsets of operations, may include operations performed in response to commands from the host processor 210 or a controller 215, or operations performed without commands from a host processor 210 or a controller 215 (e.g., operations determined by or initiated by a logic block 225, operations determined by or initiated by an interface block 220, operations determined by or initiated by an interface block 245, operations determined by or initiated by a logic block 230), or various combinations thereof.

In some implementations, the system 200 may include one or more instances of non-volatile storage (e.g., non-volatile storage 235 of a die 205, non-volatile storage 270 of one or more dies 240, or a combination thereof). In some examples, a logic block 230, logic blocks 225, interface blocks 220, interface blocks 245, or a combination thereof may be configured to communicate signaling with one or more instances of non-volatile storage. For example, a logic block 230, logic blocks 225, interface blocks 220, or interface blocks 245 may be coupled with one or more instances of non-volatile storage via one or more buses (not shown), or respective contacts (not shown), where applicable, which may each include one or more signal paths operable to communicate signaling (e.g., command signaling, data signaling). In some examples, a logic block 230, one or more logic blocks 225, one or more interface blocks 220, one or more interface blocks 245, or a combination thereof may configure one or more operations based on information (e.g., instructions, configurations, parameters) stored in one or more instances of non-volatile storage. Additionally, or alternatively, in some examples, a logic block 230, one or more logic blocks 225, one or more interface blocks 220, one or more interface blocks 245, or a combination thereof may write information (e.g., configuration information, evaluation information) to be stored in one or more instances of non-volatile storage. In some examples, such non-volatile storage may include fuses, antifuses, or other types of one-time programmable storage elements, or any combination thereof.

In some implementations, the system 200 may include one or more sensors (e.g., one or more sensors 237 of a die 205, one or more sensors 275 of one or more dies 240, or a combination thereof). In some implementations, a logic block 230, logic blocks 225, interface blocks 220, interface blocks 245, or a combination thereof may be configured to receive one or more indications based on measurements of one or more sensors of the system 200. For example, a logic block 230, logic blocks 225, interface blocks 220, or interface blocks 245 may be coupled with one or more sensors via one or more buses (not shown), or respective contacts (not shown). Such sensors may include temperature sensors, current sensors, voltage sensors, counters, and other types of sensors. In some examples, a logic block 230, one or more logic blocks 225, one or more interface blocks 220, one or more interface blocks 245, or a combination thereof may configure one or more operations based on output of the one or more sensors. For example, a logic block 230 may configure one or more operations of logic blocks 225 or interface blocks 220 based on signaling (e.g., indications, data) received from the one or more sensors. Additionally, or alternatively, a logic block 225 or an interface block 220 may generate access signaling for transmitting to a corresponding interface block 245 based on one or more sensors.

In some examples, circuitry of logic blocks 225, interface blocks 220, interface blocks 245, or a logic block 230, or any combination thereof may include components (e.g., transistors) formed at least in part from doped portions of a substrate of the respective die. In some examples, a substrate of a die 205 may have characteristics (e.g., materials, material characteristics, physical shapes or dimensions) that are different from those of a substrate of a die 240. Additionally, or alternatively, in some examples, transistors formed from a substrate of a die 205 may have characteristics (e.g., manufacturing characteristics, performance characteristics, physical shapes or dimensions) that are different from transistors formed from a substrate of a die 240 (e.g., in accordance with different transistor architectures, in accordance with different transistor designs).

In some examples, the interface blocks 220 may support a layout for one or more components within the interface blocks 220. For example, the layout may include pairing components to share an access port (e.g., a command port, a data port). Further, in some examples, the layout may support interfaces for a controller 215 (e.g., a host interface 216) that are different from interfaces for an interface block 245 (e.g., via the buses 221). For instance, a host interface 216 may be synchronous and have separate channels for read and write operations, while an interface between an interface block 220 and one or more interface blocks 245 may be asynchronous and support both read and write operations with the same channel. In some examples, signaling of a host interface 216 may be implemented with a deterministic timing (e.g., deterministic between a controller 215 and a logic block 225 or one or more interface blocks 220), which may be associated with a configured timing between a first signal and a responsive second signal. In some examples, signaling between an interface block 220 and one or more interface blocks 245 may be implemented with a timing that is different from timing of a host interface 216 (e.g., in accordance with a different clock frequency, in accordance with a timing offset, such as a phase offset), which may be deterministic or non-deterministic.

A die 240 may include one or more units 265 (e.g., modules) that are separated from a semiconductor wafer having a pattern (e.g., a two-dimensional pattern) of units 265. Although each die 240 of the system 200 is illustrated with a single unit 265 (e.g., unit 265-a-1 of die 240-a-1, unit 265-a-2 of die 240-a-2), a die 240 in accordance with the described techniques may include any quantity of units 265, which may be arranged in various patterns (e.g., sets of one or more units 265 along a row direction, sets of one or more units 265 along a column direction, among other patterns). Each unit 265 may include at least the circuitry of a respective interface block 245, along with memory array(s) 250, a bus 251, a bus 246, and one or more contacts 247 corresponding to the respective interface block 245. In some examples, where applicable, each unit 265 may also include one or more buses 255, contacts 256, contacts 257, or contacts 260 (e.g., associated with a respective interface block 245 of a unit 265 of a different die 240), which may support various degrees of stackability or modularity among or via units 265 of other dies 240. Although examples of non-volatile storage 270) and sensors 275 are illustrated outside units 265, in some other examples, non-volatile storage 270, sensors 275, or both may additionally, or alternatively, be included in units 265.

In some examples, the interface blocks 220 may include circuitry configured to receive first access command signaling (e.g., from a host processor 210, from a controller 215, from a logic block 225, via a host interface 216, via one or more contacts 212 from a host processor 210 or controller 215 external to a die 205, based on a request from a host application), and to transmit second access command signaling to the respective (e.g., coupled) interface block 245 based on (e.g., in response to) the received first access command signaling. The interface blocks 245 may accordingly include circuitry configured to receive the second access command signaling from the respective interface block 220 and, in some examples, to access a respective set of one or more memory arrays 250 based on (e.g., in response to) the received second access command signaling. In various examples, the first access command signaling may include access commands that are associated with a type of operation (e.g., a read operation, a write operation, a refresh operation, a memory management operation), which may be associated with an indication of an address of the one or more memory arrays 250 (e.g., a logical address, a physical address). In some examples, the first access command signaling may include an indication of a logical address associated with the memory arrays 250, and circuitry of an interface block 220 may be configured to generate the second access command signaling to indicate a physical address associated with the memory arrays 250 (e.g., a row address, a column address, using a logical-to-physical (L2P) table or other mapping or calculation functionality of the interface block 220).

In some examples, to support write operations of the system 200, circuitry of the interface blocks 220 may be configured to receive (e.g., from a host processor 210, from a controller 215, from a logic block 225) first data signaling associated with the first access command signaling, and to transmit second data signaling (e.g., associated with second access command signaling) based on received first access command signaling and first data signaling. The interface blocks 245 may accordingly be configured to receive second data signaling, and to write data to one or more memory arrays 250 (e.g., in accordance with an indicated address associated with the first access command signaling) based on the received second access command signaling and second data signaling. In some examples, the interface blocks 220 may include an error control functionality (e.g., error detection circuitry, error correction circuitry, error correction code (ECC) logic, an ECC engine) that supports the interface blocks 220 generating the second data signaling based on performing an error control operation using the received first data signaling (e.g., detecting or correcting an error in the first data signaling. determining one or more parity bits to be conveyed in the second data signaling and written with the data).

In some examples, to support read operations of the system 200, circuitry of the interface blocks 245 may be configured to read data from the memory arrays 250 based on received second access command signaling, and to transmit first data signaling based on the read data. The interface blocks 220 may accordingly be configured to receive first data signaling, and to transmit second data signaling (e.g., to a host processor 210, to a controller 215, to a logic block 225) based on the received first data signaling. In some examples, the interface blocks 220 may include an error control functionality that supports the interface blocks 220 generating the second data signaling based on performing an error control operation using the received first data signaling (e.g., detecting or correcting an error in the first data signaling, which may include a calculation involving one or more parity bits received with the first data signaling).

In some examples, access command signaling that is transmitted to the interface blocks 245, among other signaling, may be generated (e.g., based on access command signaling received from a host processor 210, based on initiation signaling received from a host processor 210, without receiving or otherwise independent from signaling from a host processor 210) in accordance with various determination or generation techniques configured at the interface blocks 220 or the logic blocks 225 (e.g., based on a configuration for accessing memory arrays 250 that is modified at the interface blocks 220 or the logic blocks 225). In some examples, such techniques may involve signaling or other coordination with a logic block 230, a logic block 225, a host processor 210, one or more controllers 215, one or more instances of non-volatile storage, one or more sensors, or any combination thereof. Such techniques may support the interface blocks 220 or logic blocks 225 configuring aspects of the access operations performed on the memory arrays 250 by a respective interface block 245, among other operations. For example, interface blocks 220 or logic blocks 225 may include evaluation circuitry, access configuration circuitry, signaling circuitry, scheduling circuitry, repair circuitry, refresh circuitry, error control circuitry, adverse access (e.g., row hammer) mitigation circuitry, and other circuitry operable to configure operations associated with one or more dies (e.g., operations associated with accessing memory arrays 250 of the dies 240).

In some examples, functionality of a die 205 may be implemented as a semiconductor unit (e.g., a semiconductor system) that is formed with multiple semiconductor die portions (e.g., semiconductor chiplets, relatively smaller semiconductor dies), and each die portion may include respective portions of circuitry associated with the die 205. For example, a unit 280 may represent a portion of the circuitry components included in a die portion (e.g., in a chiplet), and the die portion may include an integer multiple of units 280. In some examples, each semiconductor die portion of a semiconductor unit may include different respective portions of circuitry. As a non-limiting example, a semiconductor unit (e.g., having the functionality of a die 205) may be formed by one or more first die portions having one or more units 280-a-1 and one or more second die portions having one or more units 280-a-2. The one or more units 280-a-1 may include one or more interface blocks 220, a logic block 225, or any combination thereof, and the one or more units 280-a-2 may include a host processor 210, one or more controllers 215, a logic block 230, or any combination thereof.

To manufacture a system 200, among other stacked semiconductor systems, semiconductor wafers that include multiple die units may be stacked and coupled (e.g., bonded) together, and respective stacks of coupled die units may be separated (e.g., cut, divided, singulated) from the stack of semiconductor wafers (e.g., rather than selecting individual semiconductor dies for stacking and coupling). Wafers with a relatively high yield of die units, such as wafers that include relatively fewer die units with defects (e.g., failures), may be selected for inclusion in a wafer stack. However, a non-perfect yield of the wafers may be compounded in the stack of wafers, such that a yield of a resulting stack of die units separated from the wafer stack may be reduced. For example, an eight-high array die stack that is separated from a stack of wafers that each have approximately 90% yield may have a yield of approximately 40%. As such, performance (e.g., latency, bandwidth, storage capacity) or yield of semiconductor systems may be adversely affected by such stacking.

In accordance with techniques described herein, a system 200 may be formed from wafers that are divided into die units (e.g., each corresponding to a die 240 or a die 205) having multiple sections, and the sections may be coupled as die unit section stacks through a stack of wafers. For example, each section of a die unit corresponding to a die 240 may include one or more units 265, and a die unit corresponding to a die 205 may include at least a respective unit 280 for coupling with the units 265 of a stack of die units corresponding to one or more dies 240. After stacking the semiconductor wafers (e.g., before or after singulation of die stacks from the stacked wafers), functionality of the die unit section stacks (e.g., of the units 265, of at least the stacked dies 240) may be evaluated. If a die unit section stack is found to include an error or relatively low performance, the die unit section stack may be disabled, such that other die unit section stacks of a stacked die assembly (e.g., of a system 200) may be operated (e.g., operated in accordance with a capacity or throughput associated with the remaining memory die unit section stacks).

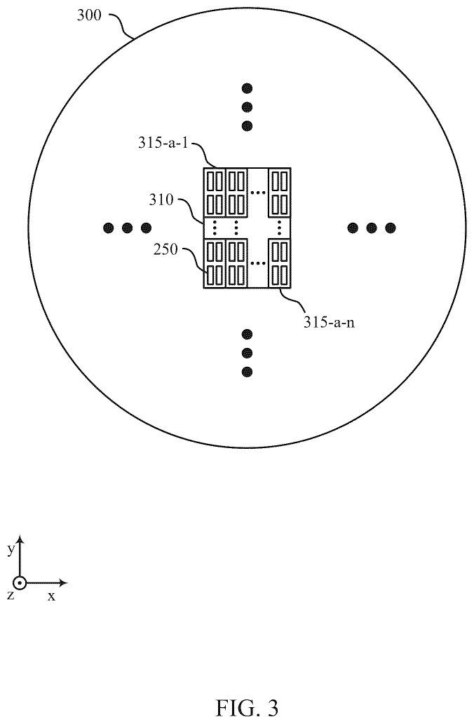

FIG. 3 shows an example of a wafer 300 (e.g., a semiconductor wafer, a semiconductor component) that supports section yielding in stacked memory architectures in accordance with examples as disclosed herein. Aspects of a wafer 300 may be described with reference to an x-direction, a y-direction, and a z-direction of the illustrated coordinate system, with the illustration of FIG. 3 depicting aspects of a wafer 300 in an xy-plane (e.g., a top-view plane) that may extend for some distance along the z-direction.

A wafer 300 may include multiple die units 310 (e.g., arranged in an xy-plane) that are configured to be separated from one another (e.g., singulated, diced). For example. the wafer 300 may be a semiconductor wafer on which a set of the die units 310 are formed, such as using various additive operations, subtractive operations, converting operations, doping operations, or a combination thereof, among other types of operations. At least some features of each of the die units 310 may be divided into (e.g., may be included in) multiple die unit sections 315 (e.g., die unit section 315-a through die unit section 315-n of the illustrated die unit 310). In some examples, a die unit 310 may include one or more aspects of a die 240, and each of the die unit sections 315 may include one or more memory arrays 250 and circuitry for operating the memory arrays 250. For example, each die unit section 315 may include one or more units 265 (e.g., one interface block 245, multiple interface blocks 245). In some other examples, a die unit 310 may include one or more aspects of a die 205, such as including one or more interface blocks 220 and a logic block 225, where applicable, for each of the die unit sections 315 of another die unit 310 (e.g., of a die 240) to be stacked on the die unit 310 of the die 205.

The wafer 300 may be stacked with other wafers 300 along the z-direction, such that the die units 310 and associated circuitry of each of the wafers 300 may be coupled. For example, one or more wafers 300 including multiple die units 310 may be coupled (e.g., bonded, fused) together and then cut into stacks of die units 310 (e.g., systems 200), rather than selecting individual dies (e.g., singulated dies 240, singulated dies 205, or both) for bonding. One or more of the wafers 300 with relatively higher yield (e.g., with relatively fewer die units 310 with defects or failures) may be selected for bonding, however, the non-perfect yield of the wafers 300 may be compounded in the stack of wafers such that a yield of resulting die stacks may be reduced (e.g., a 8-high die stack from a stack of wafers with ˜90% yield may have a yield of ˜40%). As such, performance (e.g., latency, bandwidth, storage capacity) or yield of stacked semiconductor systems may be adversely affected by such stacking.

To support various granularities of sparing and a higher yield of the stacks of the die units 310, a semiconductor system that implements a stacked architecture may support grouping stacks of die unit sections 315 within a stack of the wafers 300 according to operable states of the die unit sections 315. For example, multiple wafers 300 may be bonded such that die units 310 (e.g., and the die unit sections 315) of the wafers 300 may be coupled together in stacks. After stacking the wafers 300 (e.g., before or after singulation of stacks of die units 310 from the stacked wafers 300), functionality of the stacks of die unit sections 315 may be evaluated. If a stack of die unit sections 315 is found to include an error or relatively low performance, the stack of die unit sections 315 may be disabled, such that other stacks of die unit sections 315 (e.g., of a given stack of die units 310) may be operated (e.g., operated in accordance with a capacity or throughput associated with the remaining stacks of die unit sections 315).

By supporting section yielding based on error detection, the yield of stacks of the die units 310 may be increased, for example, by supporting the disabling of failed die unit sections 315 and the grouping (e.g., use) of error-free or relatively high-performing die unit sections 315. As such, performance of stacks of die units 310 (e.g., as systems 200), including bandwidth, storage capacity, latency, may be improved. Additionally, a time-to-market of products that implement stacks of die units 310 may be reduced. For example, products released to the market may be associated with yield constraints, and improving yield via the section yielding techniques described herein may enable such constraints to be satisfied without improving manufacturing techniques to increase the yield of individual wafers 300, which may involve a delay before such improvements are realized. Additionally, the section yielding techniques described herein may reduce costs as a final yield of stacks of die units 310 may be unknown until after they are formed. Accordingly, if a yield fails to meet yield constraints, an entire stack of die units 310 may be discarded. Thus, improving yield of stacks of the die units 310 using the section yielding techniques described herein may increase the likelihood that yield constraints are met, thereby reducing costs of manufacturing the stacks of die units 310.

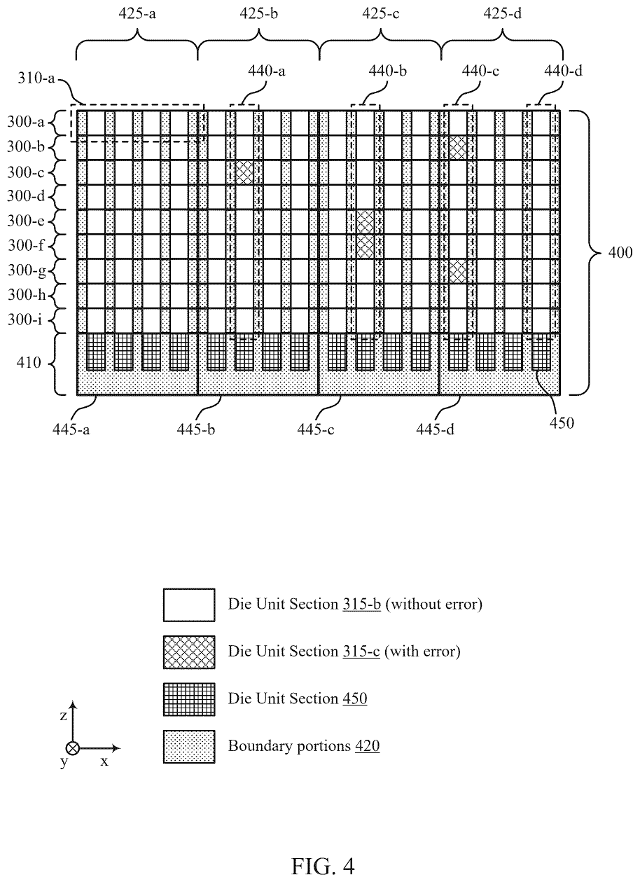

FIG. 4 shows an example of a wafer assembly 400 (e.g., a semiconductor assembly, a semiconductor system, a stack of semiconductor wafers, a stack of semiconductor components) that supports section yielding in stacked memory architectures in accordance with examples as disclosed herein. The wafer assembly 400 illustrates an example of a stack of wafers 300 that each include one or more die units 310-a. Each of the die units 310-a may be divided into (e.g., may include) die unit sections 315 (e.g., die unit sections 315-b without errors, die unit sections 315-c with one or more errors). In the example of wafer assembly 400, each of the die unit sections 315 may include one or more units 265 (e.g., one or more interface blocks 245 and corresponding memory array(s) 250), though other examples may include other arrangements of sectioned semiconductor circuitry. Aspects of the wafer assembly 400 may be described with reference to an x-direction, a y-direction, and a z-direction of the illustrated coordinate system, with the illustration of FIG. 4 depicting aspects of the wafer assembly 400 in an xz-plane (e.g., a cross-sectional plane) that may extend for some distance along the y-direction.

Although the illustrated example of a wafer assembly 400 includes nine wafers 300 each including four die units 310, a wafer assembly 400, or wafers 300 thereof may include any quantity of one or more wafers 300 in a stack, each having any quantity of one or more die units 310, which may include a pattern of die units 310 distributed in various patterns in an xy-plane (e.g., along the x-direction, along the y-direction). Further, although non-limiting examples of a wafer assembly 400 are described with reference to memory systems, memory sub-systems, memory devices, or a combination thereof, examples of a wafer assembly 400 are not so limited. For example, aspects of the present disclosure may be applied as well to any computing system, computing sub-system, processing system, processing sub-system, component, device, structure, or other types of systems or sub-systems used for applications such as data collecting, data processing, data storage, networking, communication, power, artificial intelligence, system-on-a-chip, control, telemetry, sensing and monitoring, digital entertainment, or any combination thereof.

In the illustrated example, die units 310 may be separated by or through boundary portions 420 of a wafer 300, where such boundary portions 420 may include isolation regions (e.g., one or more dielectric materials, an electrical isolation) between die units 310, or may include conductive portions between die units 310 that are severed during separation (e.g., singulation) of a wafer 300 or a stack of wafers 300, among other implementations. Additionally, or alternatively, die unit sections 315 may be separated by boundary portions 420 of a wafer 300, where such boundary portions 420 may include isolation regions (e.g., one or more dielectric materials) between die units sections 315, or may include conductive portions between die unit sections 315 (e.g., for sharing power or signals), among other implementations. In some other examples, boundary portions 420 may be omitted from a wafer 300.

A wafer assembly 400 may include a stack of multiple wafers 300 (e.g., wafers 300-a through 300-i, memory wafers) coupled along the z-direction. In some examples, a wafer assembly 400 may also include one or more wafers 410 (e.g., one or more logic wafers, one or more processor wafers). A wafer 410 may include one or more die units 445 (e.g., die units 445-a through 445-d, logical die units), each of which may include circuitry that is divided among multiple die unit sections 450 (e.g., logical die unit sections). In the illustrated example, die units 445 may be separated by or through boundary portions 420 of a wafer 410, where such boundary portions 420 may include isolation regions (e.g., one or more dielectric materials, an electrical isolation) between die units 445, or may include conductive portions between die units 445 that are severed during separation (e.g., singulation) of a wafer 410, or of a wafer 410 bonded with a stack of wafers 300, among other implementations. Additionally, or alternatively, die unit sections 450 may be separated by boundary portions 420 of a wafer 410, where such boundary portions 420 may include isolation regions (e.g., one or more dielectric materials) between die units sections 450, or may include conductive portions between die unit sections 450 (e.g., for sharing power or signals), among other implementations. In some other examples, boundary portions 420 may be omitted from a wafer 410.

Each die unit section 450 may, for example, include one or more interface blocks 220 corresponding to the die unit sections 315 stacked with the die unit section 450 (e.g., along the z-direction), such as including a respective interface block 220 for each of the die unit sections 315 of a stack, among other implementations. In some examples, a die unit section 450 may also include a logic block 225 corresponding to the stack of die unit sections 315. Other circuitry of a die unit 445, which may be outside die unit sections 450, may include aspects of a memory system controller 140, local controller(s) 150, a logic block 230, one or more controllers 215, a processor 125, a host system controller 120, a host processor 210, or a combination thereof. In various examples, non-volatile storage 235 and sensor(s) 237 of die units 445 may be included in die unit sections 450, or be outside die unit sections 450, or both. In some other examples, a wafer 410 may be omitted from a wafer assembly 400.

The wafers (e.g., wafers 300, a wafer 410, where applicable) of a wafer assembly 400 may be coupled together in a stack along the z-direction. In some examples, coupling the wafers of a wafer assembly 400 may include fusing (e.g., bonding) respective conductive materials of respective contacts of the die units 310-a (e.g., contacts 222, contacts 247, contacts 256, contacts 257, contacts 260). As such, the wafer assembly 400 may include multiple coupled die unit stacks 425 (e.g., die unit stacks 425-a through 425-d), corresponding to stacks of die units 310-a that are coupled along the z-direction. In some examples, coupling the wafers 300 may include coupling die unit sections 315 to form die unit section stacks 440 (e.g., die unit section stacks 440-a through 440-d), corresponding to stacks of die unit sections 315 that are coupled along the z-direction. In some examples, die units 445 may include one or more die unit sections 450 that each include circuitry for operating one or more memory arrays of a respective die unit section stack 440. That is, each die unit 445 may be coupled with one or more of the die unit section stacks 440 of the die unit stacks 425. Respective die unit stacks 425 may be cut from the wafer assembly 400, where each die unit stack 425 includes one or more of die unit section stacks 440. For examples in which a wafer 410 is coupled with wafers 300, the wafer 410 may also be cut such that each of the die unit stacks 425 includes a respective die unit 445.

Aspects of a wafer assembly 400 may support various techniques for evaluating functionality (e.g., one or more functions) of die unit section stacks 440, which may include evaluating whether a die unit section stack 440, or a die unit section 315 thereof, includes one or more errors (e.g., operational errors, memory access errors, communication errors, coupling errors such as electrical discontinuity). For example, one or more functions of each of the die unit section stacks 440, or a die unit sections 315 thereof, may be evaluated at various stages of the manufacturing and operating processes to determine whether to perform section yielding operations associated with the die unit stacks 425. In some examples, a function of each die unit section 315 may be evaluated (e.g., by a manufacturing system, by a tester) before the coupling of wafers 300, before coupling with a wafer 410, or both. For instance, coupling of die units 445 and die unit stacks 425 may occur after a function of die unit sections 315 of each die unit 310-a has been evaluated, or after a function of die unit section stacks 440 has been evaluated (e.g., after coupling of wafers 300, as a collective evaluation of multiple die unit sections 315), or both. Additionally, or alternatively, a function of each of the wafers 300 may be evaluated prior to the coupling of the wafers 300. In some cases, a function of each die unit section 315 may be evaluated after coupling of die units 445 and the die unit stacks 425. For example, wafers 300 may be coupled together to form the wafer assembly 400 after which the function of each die unit section stack 440, or each die unit section 315, may be evaluated. In some examples, a function of each die unit section stack 440, or each die unit section 315, may be evaluated after respective die unit stacks 425 are separated from a wafer assembly 400. Additionally, or alternatively, a function of each die unit section stack 440, or each die unit section 315, may be evaluated after respective dies including a die unit 445 are coupled with a respective stack of dies including a die unit stack 425, among other implementations.

Evaluating functionality of die unit sections 315 or die unit section stacks 440 may support the detection of one or more errors associated with a given die unit section 315 or die unit section stack 440 to determine whether to perform section yielding for the associated die unit 310-a or die unit stack 425. For example, evaluating the function of a die unit section may include performing one or more operations (e.g., biasing operations, signaling operations, memory access operations) to determine whether components of the die unit section 315 are functioning properly, or whether an error (e.g., a failure) associated with a given component exists. In some cases, evaluating a function of a die unit section 315 or a die unit section stack 440 may include evaluating whether the associated memory arrays (e.g., of the die unit sections 315) or the associated circuitry for operating the memory arrays are accessible, satisfy a threshold capacity, satisfy an operating parameter, satisfy an electrical continuity, or a combination thereof. In some examples, evaluating a function of a die unit section stack 440 may include evaluating electrical continuity (e.g., fusion) of one or more contacts 247, one or more contacts 257, and one or more contacts 222, or a combination thereof. In some examples, evaluating the function of a die unit section 315, or a die unit section stack 440, may be performed after coupling die unit section stacks 440 with die unit sections 450. For example, circuitry associated with a die unit 445 (e.g., a logic block 230, an interface block 220) associated with the die unit sections 315 may be used to evaluate respective functions of the die unit sections 315 at a finer granularity than circuitry of a tester used to evaluate the respective functions before the formation of the die unit section stacks 440. As such, in some cases, relatively more types of errors may be detected as part of an evaluation after the formation of the die unit section stacks 440 than as part of an evaluation before such a formation (e.g., before coupling of wafers 300).

In some examples, an error associated with a die unit section 315, or a die unit section stack 440, may be detected during operation of a die unit stack 425 (e.g., during evaluation operations, during operations in an assembled or integrated condition, in a deployment of a stack, after separation from a wafer assembly 400). It may be determined that one or more die unit sections 315 include an error, while one or more other die unit sections 315 may not include an error. In some examples, an error may be detected by an interface block 245, or an interface block 220, or other related circuitry based on a failure of an attempted access operation. In some examples, an interface block 245, an interface block 220, or a logic block 225 may indicate (e.g., transmit an indication of) an error to a die unit 445 of the die unit stack 425. For example, circuitry of a die unit stack 425-b (e.g., circuitry of a die unit section 315, an interface block 220 of the die unit 445-b) may determine that the die unit section stack 440-a includes an error, and may transmit an indication of the error to a component of the die unit 445-b. In some examples, it may be determined that more than one die unit section 315 of a die unit section stack 440 includes an error. For example, circuitry may determine that the die unit section stack 440-c may include two die unit sections 315-c with an error, and may transmit an indication of the errors to the die unit 445-d. In some examples, a die unit stack 425 (e.g., a set of die unit section stacks 440) may include die unit sections 315 without errors, while in other examples a die unit stack 425 may include one or more die unit sections 315 with errors. For example, the die unit stack 425-a may include die unit section stacks 440 that each include die unit sections 315-b without errors and may be fully-functioning, while the die unit stack 425-c may include the section stack 440-b that includes the die unit sections 315-c with errors included at the wafer 300-e and at the wafer 300-f and thus may be partially-functioning.

Disabling one or more die unit section stacks 440 may be performed based on the detection of die unit section stacks 440, or die unit sections 315 thereof, having one or more errors. For example, in response to evaluating the functionality of the die unit section stacks 440 and determining that one or more of the die unit sections 315 includes an error (e.g., die unit sections 315-c with an error), circuitry associated with the die unit section stacks 440 may disable the die unit section stacks 440 that include the die unit sections 315-c. That is, one or more of the die unit sections stacks 440 may be disabled in the case that they are found to include one or more errors (e.g., include one or more die unit sections 315-c), while one or more die unit sections stacks 440 may remain enabled in the case that they are found to not include any errors (e.g., not include die unit sections 315-c). In some examples, disabling the die unit section stacks 440 may include setting one or more one-time-programmable memory elements associated with the die unit section stacks 440. For example, circuitry associated with the die unit section stacks 440 may disable the die unit section stacks 440 that include an error by setting a one-time-programmable memory element included (e.g., located) inside the wafers 300 (e.g., as non-volatile storage 270) or outside the wafers 300 (e.g., as non-volatile storage 235). Additionally, or alternatively, disabling the die unit section stacks 440 may include disabling a connection with or between circuitry of a die unit section 450 and a die unit section stack 440 that includes an error. For example, disabling the die unit section stacks 440 may include disabling a connection with or between one or more contacts 247, with or between one or more contacts 256, with or between one or more contacts 257, with or between one or more contacts 222, or a combination thereof.

By supporting section yielding based on these and other techniques for error detection, a yield of die unit stacks 425 may be increased, for example, by disabling failed die unit section stacks 440, by grouping of error-free die unit sections 315, or both. As such, performance of the die unit stacks 425, including bandwidth, storage capacity, latency, may be improved. Additionally, a time-to-market of products that implement the die units 310-a in a stacked architecture may be improved. For example, products released to the market may be associated with yield constraints, and improving yield via the section yielding techniques described herein may enable such constraints to be satisfied without improving manufacturing techniques to increase the yield of individual wafers 300, which may involve a delay before such improvements are realized. Additionally, the section yielding techniques described herein may reduce costs as a final yield of die unit stacks 425 may be unknown until after it is formed (e.g., coupled with die units 445). Accordingly, if a yield fails to meet yield constraints, entire die unit stacks 425 may be discarded. Thus, improving yield of the die unit stacks 425 using the section yielding techniques described herein may increase the likelihood that yield constraints are met, thereby reducing costs of manufacturing the die unit stacks 425.

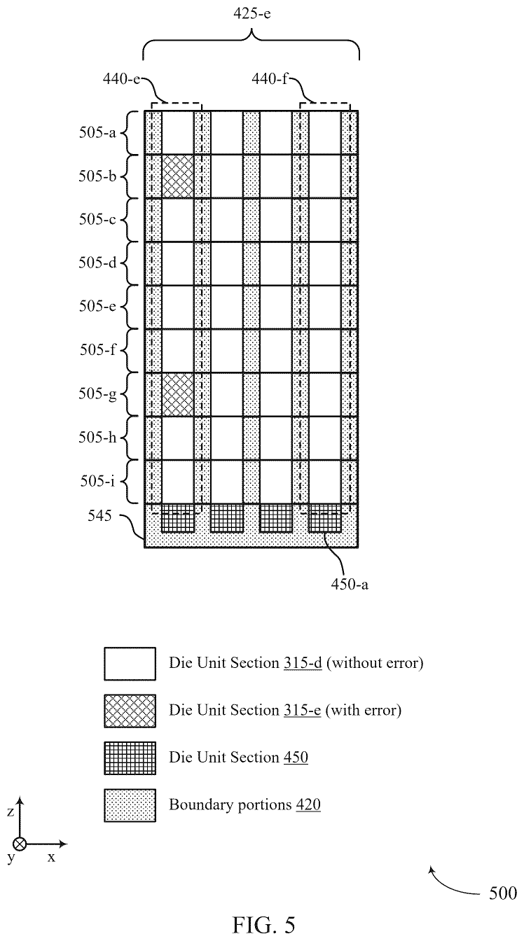

FIG. 5 shows an example of a die assembly 500 (e.g., a semiconductor assembly, a semiconductor system, a stack of semiconductor dies, a stack of semiconductor components) that supports section yielding in stacked memory architectures in accordance with examples as disclosed herein. Aspects of the die assembly 500 may be described with reference to an x-direction, a y-direction, and a z-direction of the illustrated coordinate system, with the illustration of FIG. 5 depicting aspects of the die assembly 500 in an. xz-plane (e.g., a cross-sectional plane) that may extend for some distance along the y-direction.

The die assembly 500 illustrates an example of a stack of dies 505 that are coupled together (e.g., in a stack along the z-direction), where each of the dies 505 may correspond to a respective die unit 310. In some examples, the die assembly 500 may be an example of a singulation of the die unit stack 425-d from a wafer assembly 400. Each of the dies 505 may include die unit sections 315 (e.g., die unit sections 315-d without an error, die unit sections 315-e with an error), which may be coupled along the z-direction. Each of the die unit sections 315 may include one or more memory arrays and circuitry for operating the memory arrays, and die unit sections 315 may be coupled in die unit section stacks 440. In some examples, each of the die unit section stacks 440 may be coupled with a die 545, which may correspond to a die unit 445-d of the wafer assembly 400. The die 545 may include one or more die unit sections 450-a that may each be coupled with a respective die unit section stack 440, and may include circuitry for operating memory arrays of the respective die unit section stack 440. In some examples, the die 545 may include a host processing system that may be operable to access the memory arrays of the dies 505 via the circuitry of the die 545 based on an application of the host processing system. Although the example of die assembly 500 includes boundary portions 420 in dies 505 and the die 545, in some other examples, at least some of such boundary portions 420 may be omitted.

One or more of the die unit section stacks 440 may be disabled based on a detection of die unit sections 315-e with one or more errors. For example, in response to determining that one or more of the die unit section stacks 440 includes an error, circuitry associated with the die unit section stacks 440 may disable the die unit section stack(s) 440 that include a die unit section 315-e with an error (e.g., disabling die unit section stack 440-e in response to determining that it includes one or more die unit sections 315-e with errors). The circuitry may not disable other die unit section stacks 440 that do not include die unit sections 315-e with errors (e.g., die unit section stack 440-f). In some examples, disabling the die unit section stack 440-e may include setting one or more one-time-programmable memory elements of the die assembly 500. For example, circuitry associated with the die unit section stack 440-e may disable the die unit section stack 440-e by setting a one-time-programmable memory element included (e.g., located) inside the die 545 or outside the die 545 (e.g., in non-volatile storage 270, in non-volatile storage 235). In some examples, disabling the die unit section stack 440-e may include disabling a connection between the circuitry of the die 545 and the die unit section stack 440-e. For example, disabling the die unit section stack 440-e may include disabling a connection with or between one or more contacts 247, with or between one or more contacts 257, with or between one or more contacts 222, or a combination thereof.

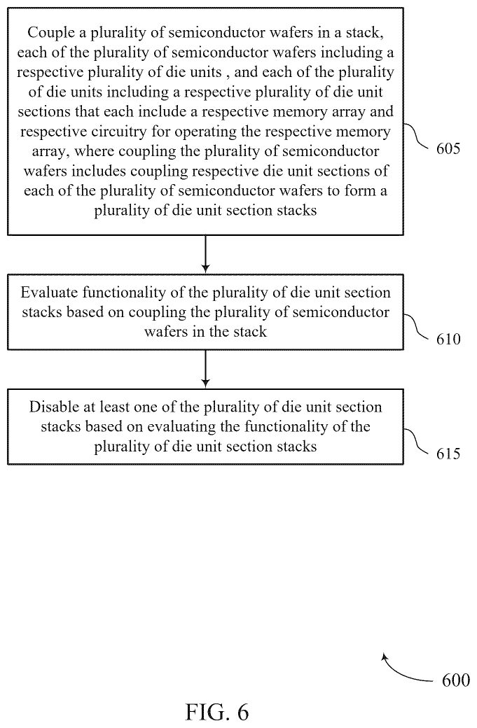

FIG. 6 shows a flowchart illustrating a method 600 that supports section yielding in stacked memory architectures in accordance with examples as disclosed herein. The operations of method 600 may be implemented by a manufacturing system or one or more controllers associated with a manufacturing system. In some examples, one or more controllers may execute a set of instructions to control one or more functional elements of a manufacturing system to perform the described functions. Additionally, or alternatively, one or more controllers may perform aspects of the described functions using special-purpose hardware.

At 605, the method may include coupling a plurality of semiconductor wafers (e.g., wafers 300) in a stack, each of the plurality of semiconductor wafers including a respective plurality of die units (e.g., die units 310), and each of the plurality of die units including a respective plurality of die unit sections (e.g., die unit sections 315) that each include a respective memory array (e.g., a memory array 155, a memory array 250) and respective circuitry (e.g., a local controller 150 or portion thereof, an interface block 245) for operating the respective memory array, where coupling the plurality of semiconductor wafers includes coupling respective die unit sections of each of the plurality of semiconductor wafers to form a plurality of die unit section stacks (e.g., die unit section stacks 440).

At 610, the method may include evaluating functionality of (e.g., operations of, coupling of, connections of) the plurality of die unit section stacks based on coupling the plurality of semiconductor wafers in the stack.

At 615, the method may include disabling at least one of the plurality of die unit section stacks based on evaluating the functionality of the plurality of die unit section stacks.

In some examples, an apparatus (e.g., a manufacturing system) as described herein may perform a method or methods, such as the method 600. The apparatus may include features, circuitry, logic, means, or instructions (e.g., a non-transitory computer-readable medium storing instructions executable by one or more controllers to control one or more functional elements of the manufacturing system), or any combination thereof for performing the following aspects of the present disclosure:

Aspect 1: A method, apparatus, or non-transitory computer-readable medium including operations, features, circuitry, logic, means, or instructions, or any combination thereof for coupling a plurality of semiconductor wafers (e.g., wafers 300) in a stack, each of the plurality of semiconductor wafers including a respective plurality of die units (e.g., die units 310), and each of the plurality of die units including a respective plurality of die unit sections (e.g., die unit sections 315) that each include a respective memory array (e.g., a memory array 155, a memory array 250) and respective circuitry (e.g., a portion of a local controller 150, an interface block 245) for operating the respective memory array, where coupling the plurality of semiconductor wafers includes coupling respective die unit sections of each of the plurality of semiconductor wafers to form a plurality of die unit section stacks (e.g., die unit section stacks 440); evaluating functionality of the plurality of die unit section stacks based on coupling the plurality of semiconductor wafers in the stack; and disabling at least one of the plurality of die unit section stacks based on evaluating the functionality of the plurality of die unit section stacks.

Aspect 2: The method, apparatus, or non-transitory computer-readable medium of aspect 1, further including operations, features, circuitry, logic, means, or instructions, or any combination thereof for separating the coupled plurality of semiconductor wafers into a plurality of die unit stacks (e.g., die unit stacks 425, stacks of dies 240, die assemblies 500), where evaluating the functionality of the plurality of die unit section stacks is based on separating the coupled plurality of semiconductor wafers into the plurality of die unit stacks.

Aspect 3: The method, apparatus, or non-transitory computer-readable medium of aspect 2, further including operations, features, circuitry, logic, means, or instructions, or any combination thereof for coupling a respective second die unit (e.g., a die unit 445 before singulation, a die 545 after singulation) with at least one of the plurality of die unit stacks after evaluating the functionality of the plurality of the die unit section stacks, each second die unit including a plurality of second die unit sections (e.g., die unit sections 450), each second die unit section including respective second circuitry (e.g., a portion of a local controller 150, an interface block 220, a logic block 225) for operating one or more memory arrays of a respective die unit section stack of the at least one of the plurality of die unit stacks.

Aspect 4: The method, apparatus, or non-transitory computer-readable medium of aspect 3, where the respective second die units each include a respective host processing system (e.g., a host system 105, a host system controller 120, a host processor 210, one or more controllers 215) operable to access the one or more memory arrays of the at least one of the plurality of die unit stacks via the respective second circuitry based on an application of the respective host processing system.

Aspect 5: The method, apparatus, or non-transitory computer-readable medium of any of aspects 1 through 4, further including operations, features, circuitry, logic, means, or instructions, or any combination thereof for coupling respective a second die unit (e.g., a die unit 445 before singulation, a die 545 after singulation) with at least one of the plurality of die unit stacks, each second die unit including a plurality of second die unit sections (e.g., die unit sections 450), each second die unit section including respective second circuitry (e.g., a portion of a local controller 150, an interface block 220) for operating one or more memory arrays of a respective die unit section stack of the at least one of the plurality of die unit stacks, where evaluating the functionality of the plurality of die unit section stacks is based on coupling the respective second die unit with the at least one of the plurality of die unit stacks.

Aspect 6: The method, apparatus, or non-transitory computer-readable medium of any of aspects 1 through 5, further including operations, features, circuitry, logic, means, or instructions, or any combination thereof for coupling a second semiconductor wafer (e.g., a wafer 410) with the plurality of semiconductor wafers in the stack, the second semiconductor wafer including a plurality of second die units (e.g., die units 445), each of the plurality of second die units including a plurality of second die unit sections (e.g., die unit sections 450), and each of the plurality of second die unit sections including respective second circuitry (e.g., a portion of a local controller 150, an interface block 220) for operating one or more memory arrays of a respective die unit section stack of the plurality of die unit section stacks, where evaluating the functionality of the plurality of die unit section stacks is based on coupling the second semiconductor wafer with the plurality of coupled semiconductor wafers.

Aspect 7: The method, apparatus, or non-transitory computer-readable medium of aspect 6, where the plurality of second die units each include a respective host processing system (e.g., a host system 105, a host system controller 120, a host processor 210, one or more controllers 215) operable to access the one or more memory arrays of the at least one of the plurality of die unit stacks via the respective second circuitry based on an application of the respective host processing system.

Aspect 8: The method, apparatus, or non-transitory computer-readable medium of any of aspects 1 through 7, further including operations, features, circuitry, logic, means, or instructions, or any combination thereof for evaluating a second functionality of each of the plurality of semiconductor wafers individually before the coupling, where coupling the plurality of semiconductor wafers is based on evaluating the second functionality of each of the plurality of semiconductor wafers individually.

Aspect 9: The method, apparatus, or non-transitory computer-readable medium of any of aspects 1 through 8, where disabling the at least one of the plurality of die unit section stacks includes operations, features, circuitry, logic, means, or instructions, or any combination thereof for setting one or more one-time-programmable memory elements (e.g., of non-volatile storage 270, of non-volatile storage 235) associated with the at least one of the plurality of die unit section stacks.

Aspect 10: The method, apparatus, or non-transitory computer-readable medium of aspect 9, where the one or more one-time-programmable memory elements associated with each of the at least one of the plurality of die unit section stacks are included in the plurality of semiconductor wafers (e.g., as a portion of non-volatile storage 270).

Aspect 11: The method, apparatus, or non-transitory computer-readable medium of any of aspects 9 through 10, where the one or more one-time-programmable memory elements associated with each of the at least one of the plurality of die unit section stacks are located outside the plurality of semiconductor wafers (e.g., as a portion of non-volatile storage 235).

Aspect 12: The method, apparatus, or non-transitory computer-readable medium of any of aspects 1 through 11, where disabling the at least one of the plurality of die unit section stacks includes operations, features, circuitry, logic, means, or instructions, or any combination thereof for disabling a connection (e.g., of an interface block 245, of an interface block 220, between an interface block 245 and an interface block 220) operable to couple the at least one of the plurality of die unit section stacks with second circuitry of a second semiconductor die (e.g., of a die 205).

Aspect 13: The method, apparatus, or non-transitory computer-readable medium of any of aspects 1 through 12, where evaluating the functionality of the plurality of die unit sections includes operations, features, circuitry, logic, means, or instructions, or any combination thereof for evaluating, for at least one of the die unit section stacks, whether the respective memory arrays or the respective circuitry for operating the respective memory arrays of the respective die unit sections are accessible, satisfy a threshold capacity, satisfy an operating parameter, satisfy an electrical continuity, or a combination thereof.

It should be noted that the aspects described herein describe possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 14: A semiconductor system (e.g., a die assembly 500), including: a plurality of semiconductor dies (e.g., dies 505) coupled in a stack, each of the plurality of semiconductor dies including a respective plurality of die unit sections (e.g., die unit sections 315) that each include a respective memory array (e.g., a memory array 155, a memory array 250) and respective circuitry (e.g., a portion of a local controller 150, an interface block 245) for operating the memory array, where respective die unit sections of each of the plurality of semiconductor dies are coupled to form a plurality of die unit section stacks (e.g., die unit section stacks 440), and where at least one of the plurality of die unit section stacks (e.g., die unit section stack 440-e) is disabled.

Aspect 15: The semiconductor system of aspect 14, where the at least one of the plurality of die unit sections is disabled based on a setting of one or more one-time-programmable memory elements (e.g., of non-volatile storage 270) associated with the at least one of the plurality of die unit section stacks and included in the plurality of semiconductor dies.

Aspect 16: The semiconductor system of any of aspects 14 through 15, further including: a second semiconductor die (e.g., a die 545) coupled with the plurality of semiconductor dies, the second semiconductor die including a plurality of second die unit sections (e.g., die unit sections 450), each second die unit section including respective second circuitry (e.g., a portion of a local controller 150, an interface block 220, a logic block 225) for operating one or more memory arrays of a respective die unit section stack of the plurality of semiconductor dies.

Aspect 17: The semiconductor system of aspect 16, where the at least one of the plurality of die unit sections is disabled based on a setting of one or more one-time-programmable memory elements (e.g., of non-volatile storage 235) associated with the at least one of the plurality of die unit section stacks and included in the second semiconductor die.

Aspect 18: The semiconductor system of any of aspects 16 through 17, where the second semiconductor die includes a host processing system (e.g., a host system 105, a host system controller 120, a host processor 210, one or more controllers 215) operable to access the one or more memory arrays of the plurality of semiconductor dies via the respective second circuitry of the second die unit sections based on an application of the respective host processing system.

Aspect 19: The semiconductor system of any of aspects 16 through 18, where the at least one of the plurality of die unit section stacks is disabled based on a connection operable to couple the at least one of the plurality of die unit section stacks with second circuitry of a second semiconductor die being disabled.

An apparatus is described. The following provides an overview of aspects of the apparatus as described herein:

Aspect 20: A semiconductor system (e.g., a wafer assembly 400, a die assembly 500) formed by a process including: coupling a plurality of semiconductor wafers (e.g., wafers 300) in a stack, each of the plurality of semiconductor wafers including a respective plurality of die units (e.g., die units 310), and each of the plurality of die units including a respective plurality of die unit sections (e.g., die unit sections 315) that each include a respective memory array (e.g., a memory array 155, a memory array 250) and respective circuitry (e.g., a local controller 150 or portion thereof, an interface block 245) for operating the respective memory array, where coupling the plurality of semiconductor wafers includes coupling respective die unit sections of each of the plurality of semiconductor wafers to form a plurality of die unit section stacks (e.g., die unit section stacks 440); evaluating functionality of the plurality of die unit section stacks based on coupling the plurality of semiconductor wafers in the stack; and disabling at least one of the plurality of die unit section stacks based on evaluating the functionality of the plurality of die unit section stacks.

Aspect 21: The semiconductor system of aspect 20, formed by the process further including: coupling respective a second die unit (e.g., a die unit 445 before singulation, a die 545 after singulation) with at least one of the plurality of die unit stacks, each second die unit including a plurality of second die unit sections (e.g., die unit sections 450), each second die unit section including respective second circuitry (e.g., a portion of a local controller 150, an interface block 220, a logic block 225) for operating one or more memory arrays of a respective die unit section stack of the at least one of the plurality of die unit stacks.

Aspect 22: The semiconductor system of aspect 21, where the respective second die units each include a respective host processing system (e.g., a host system 105, a host system controller 120, a host processor 210, one or more controller 215) operable to access the one or more memory arrays of the at least one of the plurality of die unit stacks via the respective second circuitry based on an application of the respective host processing system.

Aspect 23: The semiconductor system of any of aspects 20 through 22, formed by the process including: disabling the at least one of the plurality of die unit section stacks based on setting one or more one-time-programmable memory elements (e.g., of non-volatile storage 270, of non-volatile storage 235) associated with the at least one of the plurality of die unit section stacks.

Aspect 24: The semiconductor system of any of aspects 20 through 23, formed by the process including: disabling the at least one of the plurality of die unit section stacks based on disabling a connection (e.g., of an interface block 245, of an interface block 220, between an interface block 245 and an interface block 220) operable to couple the at least one of the plurality of die unit section stacks with second circuitry of a second semiconductor die (e.g., of a die 205).

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal: however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (e.g., in conductive contact with, connected with, coupled with) one another if there is any electrical path (e.g., conductive path) between the components that can, at any time, support the flow of signals (e.g., charge, current, voltage) between the components. A conductive path between components that are in electronic communication with each other (e.g., in conductive contact with, connected with, coupled with) may be an open circuit or a closed circuit based on the operation of the device that includes the connected components. A conductive path between connected components may be a direct conductive path between the components or may be an indirect conductive path that includes intermediate components, such as switches, transistors, or other components. In some examples, the flow of signals between the connected components may be interrupted for a time, for example, using one or more intermediate components such as switches or transistors.

The term “isolated” may refer to a relationship between components in which signals are not presently capable of flowing between the components. Components are isolated from each other if there is an open circuit between them. For example, two components separated by a switch that is positioned between the components are isolated from each other when the switch is open. When a component isolates two components, the component may initiate a change that prevents signals from flowing between the other components using a conductive path that previously permitted signals to flow.

The term “coupling” (e.g., “electrically coupling”) may refer to condition of moving from an open-circuit relationship between components in which signals are not presently capable of being communicated between the components (e.g., over a conductive path) to a closed-circuit relationship between components in which signals are capable of being communicated between components (e.g., over the conductive path). When a component, such as a controller, couples other components together, the component may initiate a change that allows signals to flow between the other components over a conductive path that previously did not permit signals to flow.

The terms “layer” and “level” may refer to an organization (e.g., a stratum, a sheet) of a geometrical structure (e.g., relative to a substrate). Each layer or level may have three dimensions (e.g., height, width, and depth) and may cover at least a portion of a surface. For example, a layer or level may be a three dimensional structure where two dimensions are greater than a third, e.g., a thin-film. Layers or levels may include different elements, components, or materials. In some examples, one layer or level may be composed of two or more sublayers or sublevels.

A switching component (e.g., a transistor) discussed herein may be a field-effect transistor (FET), and may include a source (e.g., a source terminal), a drain (e.g., a drain terminal), a channel between the source and drain, and a gate (e.g., a gate terminal). A conductivity of the channel may be controlled (e.g., modulated) by applying a voltage to the gate which, in some examples, may result in the channel becoming conductive. A switching component may be an example of an n-type FET or a p-type FET.

The description set forth herein, in connection with the appended drawings, describes example configurations and does not represent all the examples that may be implemented or that are within the scope of the claims. The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Similar components may be distinguished by following the reference label by one or more dashes and additional labeling that distinguishes among the similar components. If just the first reference label is used in the specification, the description is applicable to any one of the similar components having the same first reference label irrespective of the additional reference labels.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The descriptions and drawings are provided to enable a person having ordinary skill in the art to make or use the disclosure. Various modifications to the disclosure will be apparent to the person having ordinary skill in the art, and the techniques disclosed herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A method, comprising:
coupling a plurality of semiconductor wafers in a stack, each of the plurality of semiconductor wafers comprising a respective plurality of die units, and each of the plurality of die units comprising a respective plurality of die unit sections that each include a respective memory array and respective circuitry for operating the respective memory array, wherein coupling the plurality of semiconductor wafers comprises coupling respective die unit sections of each of the plurality of semiconductor wafers to form a plurality of die unit section stacks;
evaluating functionality of the plurality of die unit section stacks based on coupling the plurality of semiconductor wafers in the stack; and
disabling at least one of the plurality of die unit section stacks based on evaluating the functionality of the plurality of die unit section stacks.

2. The method of claim 1, further comprising:
separating the coupled plurality of semiconductor wafers into a plurality of die unit stacks, wherein evaluating the functionality of the plurality of die unit section stacks is based on separating the coupled plurality of semiconductor wafers into the plurality of die unit stacks.

3. The method of claim 2, further comprising:
coupling a respective second die unit with at least one of the plurality of die unit stacks after evaluating the functionality of the plurality of the die unit section stacks, each second die unit comprising a plurality of second die unit sections, each second die unit section comprising respective second circuitry for operating one or more memory arrays of a respective die unit section stack of the at least one of the plurality of die unit stacks.

4. The method of claim 3, wherein the respective second die units each include a respective host processing system operable to access the one or more memory arrays of the at least one of the plurality of die unit stacks via the respective second circuitry based on an application of the respective host processing system.

5. The method of claim 1, further comprising:
coupling respective a second die unit with at least one of the plurality of die unit stacks, each second die unit comprising a plurality of second die unit sections, each second die unit section comprising respective second circuitry for operating one or more memory arrays of a respective die unit section stack of the at least one of the plurality of die unit stacks, wherein evaluating the functionality of the plurality of die unit section stacks is based on coupling the respective second die unit with the at least one of the plurality of die unit stacks.

6. The method of claim 1, further comprising:
coupling a second semiconductor wafer with the plurality of semiconductor wafers in the stack, the second semiconductor wafer comprising a plurality of second die units, each of the plurality of second die units comprising a plurality of second die unit sections, and each of the plurality of second die unit sections comprising respective second circuitry for operating one or more memory arrays of a respective die unit section stack of the plurality of die unit section stacks, wherein evaluating the functionality of the plurality of die unit section stacks is based on coupling the second semiconductor wafer with the plurality of coupled semiconductor wafers.

7. The method of claim 6, wherein the plurality of second die units each include a respective host processing system operable to access the one or more memory arrays of the at least one of the plurality of die unit stacks via the respective second circuitry based on an application of the respective host processing system.

8. The method of claim 1, further comprising:
evaluating a second functionality of each of the plurality of semiconductor wafers individually before the coupling, wherein coupling the plurality of semiconductor wafers is based on evaluating the second functionality of each of the plurality of semiconductor wafers individually.

9. The method of claim 1, wherein disabling the at least one of the plurality of die unit section stacks comprises:
setting one or more one-time-programmable memory elements associated with the at least one of the plurality of die unit section stacks.

10. The method of claim 9, wherein the one or more one-time-programmable memory elements associated with each of the at least one of the plurality of die unit section stacks are included in the plurality of semiconductor wafers.

11. The method of claim 9, wherein the one or more one-time-programmable memory elements associated with each of the at least one of the plurality of die unit section stacks are located outside the plurality of semiconductor wafers.

12. The method of claim 1, wherein disabling the at least one of the plurality of die unit section stacks comprises:
disabling a connection operable to couple the at least one of the plurality of die unit section stacks with second circuitry of a second semiconductor die.

13. The method of claim 1, wherein evaluating the functionality of the plurality of die unit sections comprises:
evaluating, for at least one of the die unit section stacks, whether the respective memory arrays or the respective circuitry for operating the respective memory arrays of the respective die unit sections are accessible, satisfy a threshold capacity, satisfy an operating parameter, satisfy an electrical continuity, or a combination thereof.

14. A semiconductor system, comprising:
a plurality of semiconductor dies coupled in a stack, each of the plurality of semiconductor dies comprising a respective plurality of die unit sections that each include a respective memory array and respective circuitry for operating the memory array,
wherein respective die unit sections of each of the plurality of semiconductor dies are coupled to form a plurality of die unit section stacks, and
wherein at least one of the plurality of die unit section stacks is disabled.

15. The semiconductor system of claim 14, wherein the at least one of the plurality of die unit sections is disabled based on a setting of one or more one-time-programmable memory elements associated with the at least one of the plurality of die unit section stacks and included in the plurality of semiconductor dies.

16. The semiconductor system of claim 14, further comprising:
a second semiconductor die coupled with the plurality of semiconductor dies, the second semiconductor die comprising a plurality of second die unit sections, each second die unit section comprising respective second circuitry for operating one or more memory arrays of a respective die unit section stack of the plurality of semiconductor dies.

17. The semiconductor system of claim 16, wherein the at least one of the plurality of die unit sections is disabled based on a setting of one or more one-time-programmable memory elements associated with the at least one of the plurality of die unit section stacks and included in the second semiconductor die.

18. The semiconductor system of claim 16, wherein the second semiconductor die includes a host processing system operable to access the one or more memory arrays of the plurality of semiconductor dies via the respective second circuitry of the second die unit sections based on an application of the respective host processing system.

19. The semiconductor system of claim 16, wherein the at least one of the plurality of die unit section stacks is disabled based on a connection operable to couple the at least one of the plurality of die unit section stacks with second circuitry of the second semiconductor die being disabled.

20. A semiconductor system formed by a process comprising:
coupling a plurality of semiconductor wafers in a stack, each of the plurality of semiconductor wafers comprising a respective plurality of die units, and each of the plurality of die units comprising a respective plurality of die unit sections that each include a respective memory array and respective circuitry for operating the respective memory array, wherein coupling the plurality of semiconductor wafers comprises coupling respective die unit sections of each of the plurality of semiconductor wafers to form a plurality of die unit section stacks;
evaluating functionality of the plurality of die unit section stacks based on coupling the plurality of semiconductor wafers in the stack; and
disabling at least one of the plurality of die unit section stacks based on evaluating the functionality of the plurality of die unit section stacks.

21. The semiconductor system of claim 20, formed by the process further comprising:
coupling respective a second die unit with at least one of the plurality of die unit stacks, each second die unit comprising a plurality of second die unit sections, each second die unit section comprising respective second circuitry for operating one or more memory arrays of a respective die unit section stack of the at least one of the plurality of die unit stacks.

22. The semiconductor system of claim 21, wherein the respective second die units each include a respective host processing system operable to access the one or more memory arrays of the at least one of the plurality of die unit stacks via the respective second circuitry based on an application of the respective host processing system.

23. The semiconductor system of claim 20, formed by the process comprising:
disabling the at least one of the plurality of die unit section stacks based on setting one or more one-time-programmable memory elements associated with the at least one of the plurality of die unit section stacks.

24. The semiconductor system of claim 20, formed by the process comprising:
disabling the at least one of the plurality of die unit section stacks based on disabling a connection operable to couple the at least one of the plurality of die unit section stacks with second circuitry of a second semiconductor die.
